(19) United States
(12) Patent Application Publication
(10) Pub. No.: US 2026/0371905 A1
(43) Pub. Date: Nov. 19, 2026

(54) DISPLAY DEVICE, ELECTRONIC DEVICE INCLUDING THE SAME, AND METHOD OF MANUFACTURING DISPLAY DEVICE

(71) Applicant: Samsung Display Co., Ltd., Yongin-si (KR)

(72) Inventor: Dongjin KANG, Yongin-si (KR)

(21) Appl. No.: 19/531,564

(22) Filed: Feb. 5, 2026

(30) Foreign Application Priority Data
May 14, 2025 (KR) 10-2025-0062452

(51) Int. Cl. H10K 59/80; H10K 59/12; H10K 59/122; H10K 59/126

(52) U.S. Cl. CPC H10K 59/879; H10K 59/1201; H10K 59/122; H10K 59/126

(57) ABSTRACT

Disclosed is a display device including a light-emitting element, a bank above the light-emitting element and defining an opening overlapping the light-emitting element, a first lens inside the opening, and second lenses contacting a lens surface of the first lens.

### CROSS-REFERENCE TO RELATED APPLICATIONS

The present application claims priority to, and the benefit of, Korean Patent Application No. 10-2025-0062452, filed on May 14, 2025, in the Korean Intellectual Property Office, the entire disclosure of which is incorporated herein by reference.

### BACKGROUND

Embodiments of the present disclosure described herein relate to a display device, an electronic device including the same, and a method of manufacturing a display device.

Display devices used in various devices, such as televisions, mobile phones, tablet computers, and vehicles, have been developed. Depending on a usage environment in which information should be protected, or depending on regulations for safety, it may be suitable to limit a viewing angle of the display device. Accordingly, research on a laminated structure of the display device and an optical member included in the display device has been conducted to limit the viewing angle of the display device, but as the viewing angle is limited, light output efficiency is lowered.

### SUMMARY

Embodiments of the present disclosure provide a display device including a laminated lens structure.

Embodiments of the present disclosure also provide an electronic device including the display device.

Embodiments of the present disclosure also provide a method of manufacturing a display device including a laminated lens structure.

According to one or more embodiments, a display device includes a light-emitting element, a bank above the light-emitting element and defining an opening overlapping the light-emitting element, a first lens inside the opening, and second lenses contacting a lens surface of the first lens.

The lens surface of the first lens may protrude upwardly from an upper end of the bank.

The second lenses and the first lens may include materials having different respective refractive indices.

Upper surfaces of the first lens and the second lenses may be curved and may have different respective curvatures.

A partial area of the lens surface of the first lens may be exposed between the second lenses in plan view.

The bank may include an upper surface extending from the opening in a direction away from the light-emitting element.

The second lenses may include a second-first lens having a first refractive index and a second-second lens having a second refractive index, wherein the second-second lens is further from a center of the first lens than the second-first lens is from the center of the first lens.

The first lens may have a refractive index higher than a refractive index of the second-second lens, which is higher than a refractive index of the second-first lens.

The first lens may have a refractive index that is less than a refractive index of the second-second lens, which is less than a refractive index of the second-first lens.

The second-first lens may be provided in plural, wherein the second-second lens is provided in plural.

The light-emitting element may be provided in plural, wherein the opening is provided in plural, and wherein the light-emitting elements respectively overlap the openings.

The second lenses may overlap a corresponding one of the light-emitting elements.

The display device may further include a pixel-defining film below the bank, and defining a light-emitting opening exposing a first electrode, wherein the light-emitting element includes the first electrode, a light-emitting layer, and a second electrode above the light-emitting layer.

The display device may further include a light-shielding pattern above the pixel-defining film and below the bank.

According to one or more embodiments, an electronic device includes a display device, and a processor configured to control the display device, wherein the display device includes a light-emitting element, a bank above the light-emitting element and defining an opening overlapping the light-emitting element, a first resin pattern inside the opening and including a curved first surface protruding from the opening, and second resin patterns on the first surface of the first resin pattern and including a curved second surface in a direction opposite to the light-emitting element.

The first surface and the second surface may have different respective curvatures.

The first resin pattern and the second resin patterns may include a base resin and optical particles and may have different respective types or ratios of the optical particles.

The second resin patterns may include a second-first resin pattern having a first refractive index and a second-second resin pattern having a second refractive index, wherein the second-second resin pattern is located further outwardly from a center of the first resin pattern than the second-first resin pattern from the center of the first resin pattern.

The first resin pattern, the second-first resin pattern, and the second-second resin pattern may have different respective curvatures.

According to one or more embodiments, a method of manufacturing a display device includes forming a bank above a display panel, defining an opening overlapping a light-emitting element, and having surface energy in a range of about 20 mJ/m² to about 30 mJ/m², providing a liquid first resin material to the opening to form a first preliminary lens including a lens surface having surface tension in a range of about 26 dyne/cm to about 38 dyne/cm, curing the first preliminary lens to form a first lens, providing a liquid second resin material to form second preliminary lenses on the first lens, and curing the second preliminary lenses to form second lenses.

### BRIEF DESCRIPTION OF THE DRAWINGS

The above and other aspects of the present disclosure will become apparent by describing in detail embodiments thereof with reference to the accompanying drawings.

FIG. 1 is a block diagram of an electronic device according to one or more embodiments.

FIG. 2 is a schematic view of the electronic device according to one or more embodiments.

FIG. 3 is a perspective view of a display device according to one or more embodiments.

FIG. 4 is an exploded perspective view of the display device according to one or more embodiments.

FIG. 5 is an enlarged plan view of part AA of FIG. 4 according to one or more embodiments.

FIG. 6A is a cross-sectional view taken along the line I-I′ of FIG. 5 according to one or more embodiments.

FIG. 6B is an enlarged plan view of a portion of a display module according to one or more embodiments.

FIG. 6C is an enlarged cross-sectional view of the portion of the display module according to one or more embodiments.

FIGS. 7A-7D are plan views of a light controlling layer according to one or more embodiments.

FIG. 8 is a cross-sectional view taken along the line II-II′ of FIG. 7D according to one or more embodiments.

FIGS. 9A-9E are views for describing a method of manufacturing a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, if a first part is described as being arranged “on” a second part, this indicates that the first part is arranged at an upper side or a lower side of the second part without the limitation to the upper side thereof on the basis of the gravity direction.

Further, the phrase “in a plan view” means if an object portion is viewed from above, and the phrase “in a schematic cross-sectional view” means if a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that if an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, if a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, if a portion of a layer, a film, an area, a plate, or the like is formed on another portion, a forming direction is not limited to an upper direction but includes forming the portion on a side surface or in a lower direction. On the contrary, if a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that if an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. The terms or words used in the present specification and claims are not to be limitedly interpreted as general or dictionary meanings and should be interpreted as meanings and concepts that are consistent with aspects of the present disclosure on the basis that an inventor can be their own lexicographer to appropriately define concepts of terms to describe the embodiments in the best way.

As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The display device according to one or more embodiments may be applied to various electronic devices. The electronic device according to one or more embodiments may include the display device, and may further include a module or a device having another additional function in addition to the display device.

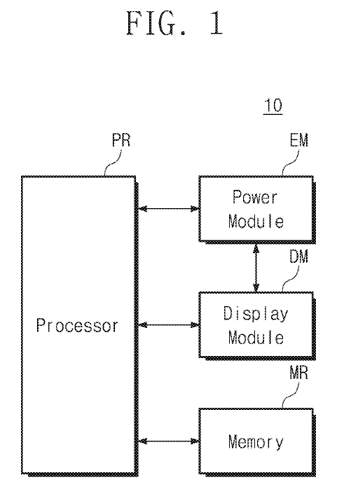

FIG. 1 is a block diagram of an electronic device according to one or more embodiments of the present disclosure. Referring to FIG. 1, an electronic device 10 according to one or more embodiments may include a display module DM, a processor PR, a memory MR, and a power module EM.

The processor PR may include at least one of a central processing unit (CPU), an application processor (AP), a graphic processing unit (GPU), a communication processor (CP), an image signal processor (ISP), or a controller.

Data information suitable for operating the processor PR or the display module DM may be stored in the memory MR. When the processor PR executes an application stored in the memory MR, an image data signal and/or an input control signal may be transmitted to the display module DM, and the display module DM may process the received signal and output image information through a display screen.

The power module EM may include a power supply module, such as a power adapter or a battery device and a power conversion module that converts power supplied by the power supply module to generate power suitable for the operation of the electronic device 10.

At least one of the components of the electronic device 10 may be included in the display device according to one or more embodiments. Further, some of individual modules functionally included inside one module may be included inside the display device, and the others thereof may be provided separately from the display device. For example, the display device may include the display module DM, and the processor PR, the memory MR, and the power module EM may be provided in the form of other devices in the electronic device 10 rather than the display device.

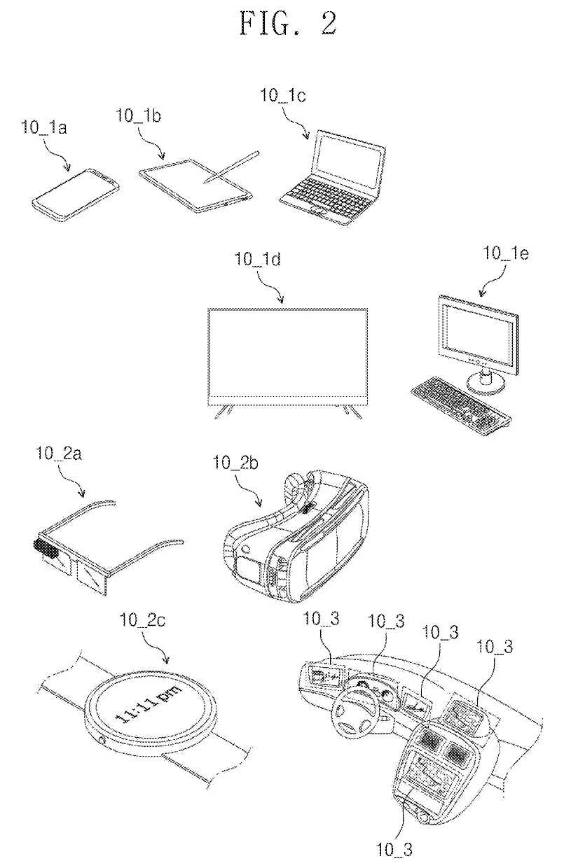

FIG. 2 is a schematic view of the electronic device according to one or more embodiments.

Referring to FIG. 2, various electronic devices to which the display device according to one or more embodiments is applied may include an image display electronic device, such as a smartphone 10_1a, a tablet PC 10_1b, a laptop computer 10_1c, a television (TV) 10_1d, and a desk monitor 10_1e, a wearable electronic device including a display module, such as a smart glasses 10_2a, a head-mounted display 10_2b, and a smart watch 10_2c, and a vehicle electronic device 10_3 including a display module, such as an instrument panel, a center fascia, a center information display (CID) located on a dashboard, and a room mirror display of a vehicle.

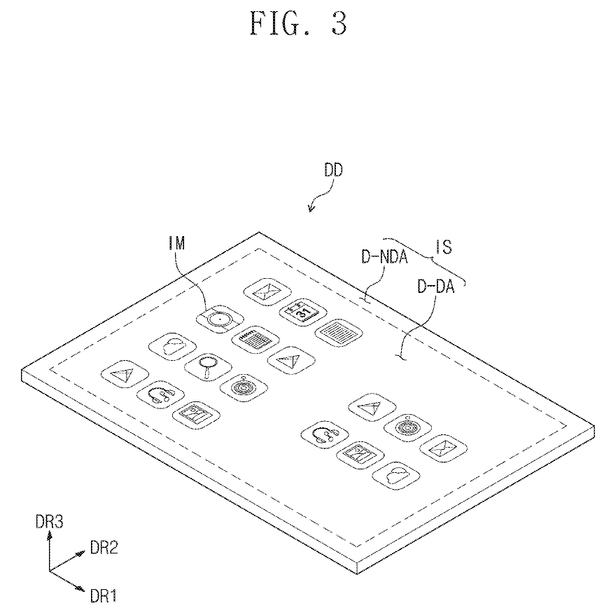

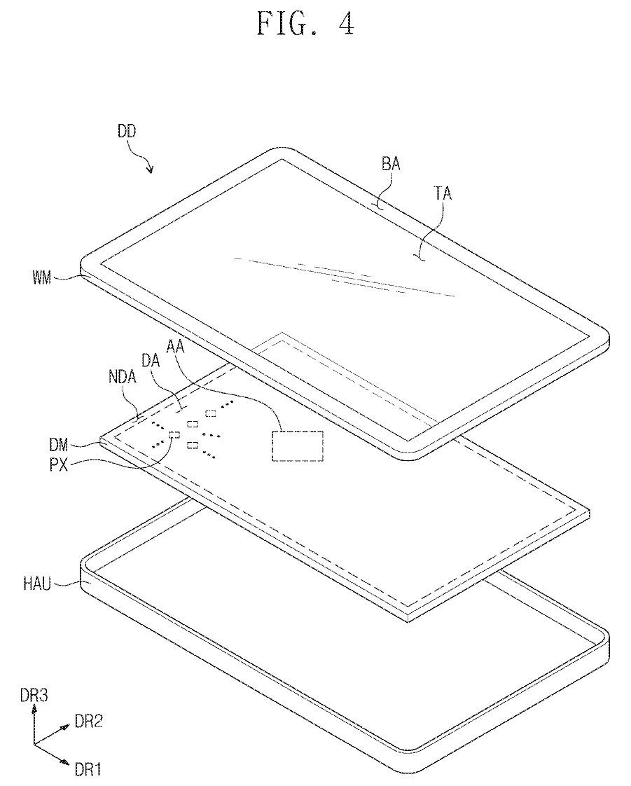

FIG. 3 is a perspective view of a display device according to one or more embodiments. FIG. 4 is an exploded perspective view of the display device according to one or more embodiments.

FIG. 3 illustrates, by way of example, a display device DD that may be applied to a tablet terminal.

Referring to FIG. 3, the display device DD may have a rectangular shape including long sides extending in a first direction DR1, and short sides extending in a second direction DR2 on a plane. However, the present disclosure is not limited thereto, and the display device DD may have various shapes, such as a circular shape or a polygonal shape.

Hereinafter, a direction substantially perpendicular to a plane defined by the first direction DR1 and the second direction DR2 is defined as a third direction DR3. In the specification, the wording “when viewed on a plane” or “in plan view” means a state viewed from the third direction DR3.

An upper surface of the display device DD may be defined as a display surface IS, and may have the plane defined by the first direction DR1 and the second direction DR2. Images IM generated by the display device DD may be provided to a user through the display surface IS.

The display surface IS may include a display part D-DA, and a non-display part D-NDA around the display part D-DA. The display part D-DA may display an image, and the non-display part D-NDA may not display an image. The non-display part D-NDA may surround the display part D-DA (e.g., in plan view), and may define an edge of the display device DD printed in a corresponding color (e.g., a predetermined color).

FIG. 4 is an exploded perspective view of the display device according to one or more embodiments.

Referring to FIG. 4, the display device DD may include a window WM, the display module DM, and an outer case HAU.

The window WM and the outer case HAU may be coupled to each other to constitute an exterior of the display device DD, and may provide an internal space in which components of the display device DD, such as the display module DM, may be accommodated.

The window WM may be located on the display module DM (as used herein, “located on” may mean “above”). The window WM may protect the display module DM from an external impact. A front surface of the window WM may correspond to the display surface IS (see FIG. 1) of the electronic device 10. The front surface of the window WM may include a transmissive area TA and a bezel area BA.

The transmissive area TA of the window WM may be an optically transparent area. The transmissive area TA of the window WM may transmit an image provided by the display module DM, and the user may visually recognize the image. The transmissive area TA may correspond to the display part D-DA (see FIG. 1) of the display device DD.

The window WM may include an optically transparent insulating material. For example, the window WM may include glass, sapphire, plastic, or the like. The window WM may have a single-layer structure or a multi-layer structure. The window WM may further include functional layers, such as a fingerprint-preventing layer, a phase control layer, and a hard coating layer, which are arranged on an optically transparent substrate.

The bezel area BA of the window WM may be an area provided by depositing, coating, or printing a material having a color (e.g., a predetermined color) on a transparent substrate. The bezel area BA of the window WM may reduce or prevent visual recognition, from the outside, of a component of the display module DM overlapping the bezel area BA. The bezel area BA may correspond to the non-display part D-NDA (see FIG. 1) of the display device DD.

The display module DM may be located between the window WM and the outer case HAU. The display module DM may display an image according to an electric signal. The display module DM may include a display area DA, and a non-display area NDA around the display area DA.

The display area DA may be an area that is activated according to an electric signal. The display area DA may be an area through which an image provided by the display module DM is emitted. The display area DA of the display module DM may overlap at least a portion of the transmissive area TA. An image output from the display area DA may be visually recognized from the outside through the transmissive area TA.

Pixels PX may be arranged in the display area DA. A light-emitting element may be located in the display area DA, and a light-emitting element may not be located in, or may be omitted from, the non-display area NDA.

The non-display area NDA may be adjacent to the display area DA. For example, the non-display area NDA may surround the display area DA (e.g., in plan view). However, the present disclosure is not limited thereto, and the non-display area NDA may be defined in various shapes. The non-display area NDA may be an area in which a driving circuit or a driving wiring line for driving elements arranged in the display area DA, various signal lines for providing electrical signals to the elements, and pads are arranged. The non-display area NDA may overlap at least a portion of the bezel area BA, and visual recognition of components of the display module DM arranged in the non-display area NDA from the outside may be reduced or prevented due to the bezel area BA.

The display module DM according to one or more embodiments may be a light-emitting display panel, but the present disclosure is not particularly limited thereto. For example, the display panel may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include a quantum dot and/or a quantum rod. Hereinafter, in one or more embodiments, a display panel 100 is described as an organic light-emitting display panel.

The outer case HAU may be located under the display module DM, and may accommodate the display module DM. The outer case HAU may include a material having relatively high rigidity. The outer case HAU may protect the display module DM by absorbing an impact applied from the outside to the display module DM, and by reducing or preventing foreign substances and/or moisture penetrating into the display module DM. The outer case HAU according to one or more embodiments may be provided in a form in which a plurality of storage members are coupled.

Meanwhile, the display device DD may further include an input-sensing module for acquiring coordinate information of an external input applied from the outside of the display device DD. The input-sensing module of the display device DD may be driven in various methods, such as a capacitive method, a resistive method, an infrared method, or a pressure method, and the present disclosure is not limited to one method.

In one or more embodiments, the input-sensing module may be located on the display module DM. The input-sensing module may be directly located on the display module DM through a continuous process, but the present disclosure is not limited thereto, and the input-sensing module may be manufactured separately from the display module DM and coupled to the display module DM by an adhesive layer.

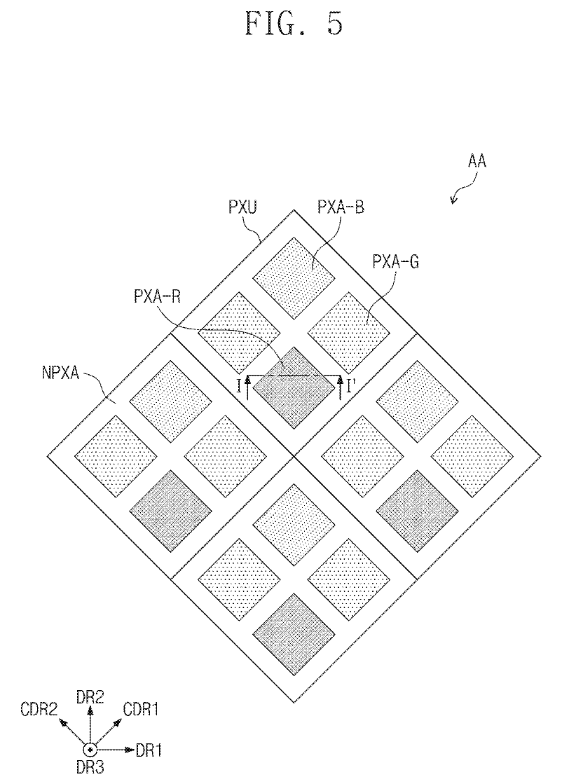

FIG. 5 is an enlarged plan view of part AA of FIG. 4 according to one or more embodiments.

An element area AA may include a plurality of pixel units PXU. The pixel unit PXU may include a first light-emitting area PXA-R, a second light-emitting area PXA-G, a third light-emitting area PXA-B, and a peripheral area NPXA. The peripheral area NPXA may surround (e.g., in plan view) the first light-emitting area PXA-R, the second light-emitting area PXA-G, and the third light-emitting area PXA-B.

The pixel units PXU may be spaced apart from each other in a first diagonal direction CDR1 and a second diagonal direction CDR2. The pixel units PXU may be arranged in an arrangement form illustrated in FIG. 5 in an entire area of the display area DA (see FIG. 4).

According to one or more embodiments, areas of the first light-emitting area PXA-R, the second light-emitting area PXA-G, and the third light-emitting area PXA-B may be the same. However, the present disclosure is not limited thereto, and the areas of the light-emitting areas may be different. For example, an area of each of the first light-emitting areas PXA-R may be greater than an area of each of the second light-emitting areas PXA-G, and may be smaller than an area of each of the third light-emitting areas PXA-B, but the present disclosure is not limited to one or more embodiments.

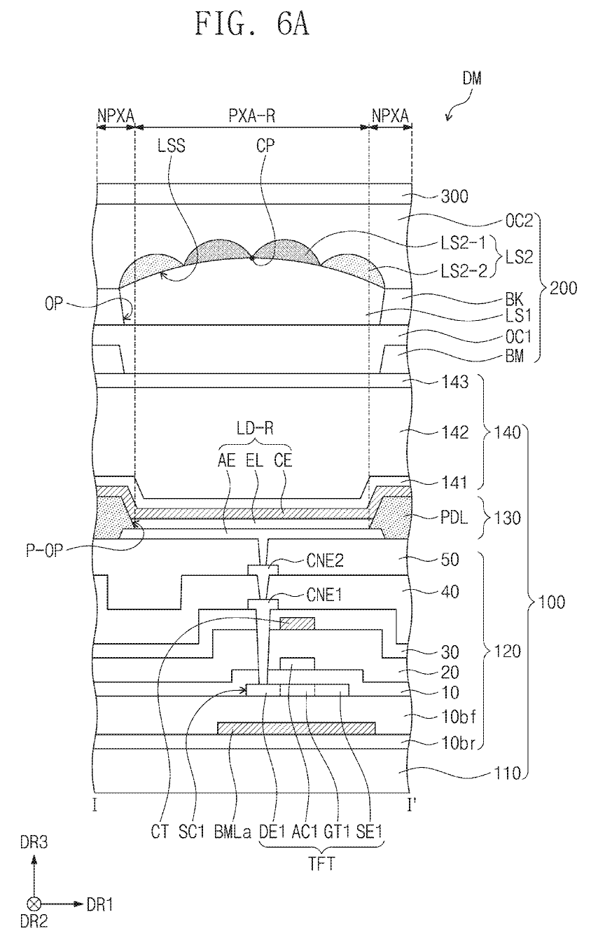

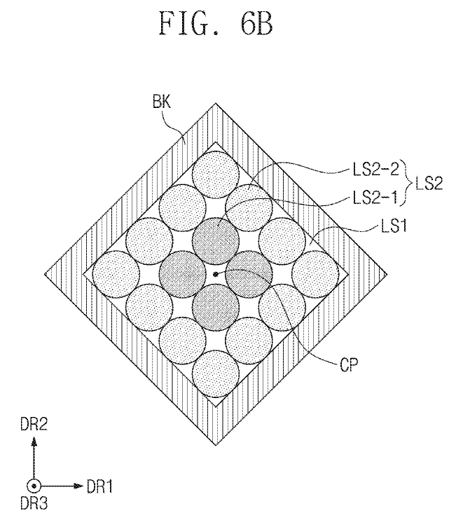

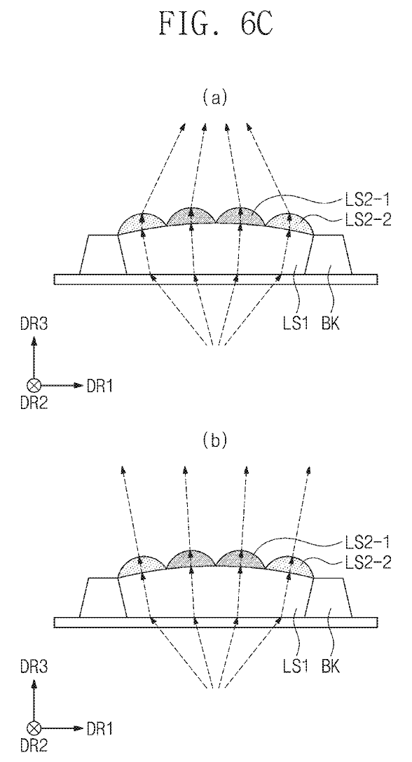

FIG. 6A is a cross-sectional view taken along the line I-I′ of FIG. 5 according to one or more embodiments.

A base substrate 110 may provide a base surface on which a circuit layer 120 is located. The base substrate 110 may be a rigid substrate or a flexible substrate that may be bent, folded, or rolled. The base substrate 110 may be a glass substrate, a metal substrate, or a polymer substrate. However, one or more embodiments of the present disclosure is not limited thereto, and the base substrate 110 may include an inorganic layer, an organic layer, or a composite material layer.

The base substrate 110 may have a multi-layer structure. For example, the base substrate 110 may include a first synthetic resin layer, a multi-layered or single-layered inorganic layer, and a second synthetic resin layer located on the multi-layered or single-layered inorganic layer. Each of the first synthetic resin layer and the second synthetic resin layer may include a polyimide-based resin, but the present disclosure is not particularly limited thereto.

A barrier layer 10br may be located on the base substrate 110 (as used herein, “located on” may mean “above”). The barrier layer 10br may reduce or prevent foreign substances introduced from the outside. The barrier layer 10br may include at least one inorganic layer. The barrier layer 10br may include a silicon oxide layer and a silicon nitride layer. Each of the silicon oxide layer and the silicon nitride layer may be provided in plurality, and the silicon oxide layers and the silicon nitride layers may be alternately laminated.

A shielding electrode BMLa may be located on the barrier layer 10br. The shielding electrode BMLa may include a metal. The shielding electrode BMLa may include molybdenum (Mo), an alloy containing molybdenum (Mo), titanium (Ti), or an alloy containing titanium (Ti) having excellent heat resistance. The shielding electrode BMLa may receive a bias voltage.

The shielding electrode BMLa may reduce or prevent an effect of an electrical potential (e.g., due to a polarization phenomenon) on a silicon transistor TFT. The shielding electrode BMLa may reduce or prevent external light reaching the silicon transistor TFT. In one or more embodiments of the present disclosure, the shielding electrode BMLa may be a floating electrode that is isolated from other electrodes or wiring lines.

A buffer layer 10bf may be located on the barrier layer 10br. The buffer layer 10bf may reduce or prevent the likelihood of a phenomenon in which metal atoms or impurities are diffused from the base substrate 110 to a semiconductor pattern SC1 on an upper side. The buffer layer 10bf may include at least one inorganic layer. The buffer layer 10bf may include a silicon oxide layer and a silicon nitride layer.

The semiconductor pattern SC1 may be located on the buffer layer 10bf. The semiconductor pattern SC1 may include a silicon semiconductor. For example, the silicon semiconductor may include amorphous silicon, polycrystalline silicon, and the like. For example, the semiconductor pattern SC1 may include low-temperature polysilicon.

The semiconductor pattern may include a first area having higher conductivity, and a second area having lower conductivity. The first area may be doped with an N-type dopant or a P-type dopant. A P-type transistor may include a doped area doped with the P-type dopant, and an N-type transistor may include a doped area doped with the N-type dopant. The second area may be a non-doped area or may be an area doped at a concentration that is lower than a concentration of the first area.

A conductivity of the first area is greater than a conductivity of the second area, and the first area may substantially serve as an electrode or a signal line. The second area may substantially correspond to an active area (or a channel) of a transistor. In other words, a portion of the semiconductor pattern may be an active area of the transistor, another portion of the semiconductor pattern may be a source area or a drain area of the transistor, and still another portion of the semiconductor pattern may be a connection electrode or a connection signal line.

A source area SE1 (or a source), an active area AC1 (or a channel), and a drain area DE1 (or a drain) of the transistor TFT may be formed from the semiconductor pattern. The source area SE1 and the drain area DE1 may respectively extend from the active area AC1 in opposite directions on a cross section.

A first insulating layer 10 may be located on the buffer layer 10bf. The first insulating layer 10 may commonly overlap the plurality of pixels PX (see FIG. 4) and may cover the semiconductor pattern. The first insulating layer 10 may include an inorganic layer and/or an organic layer, and may have a single-layer structure or a multi-layer structure.

The inorganic layer may include at least one of an aluminum oxide, a titanium oxide, a silicon oxide, a silicon nitride, a silicon oxy nitride, a zirconium oxide, or a hafnium oxide.

In one or more embodiments, the first insulating layer 10 may be a single-layered silicon oxide layer. The first insulating layer 10 and an insulating layer of a circuit layer 120, which will be described below, may be an inorganic layer and/or an organic layer, and may have a single-layer structure or a multi-layer structure. The inorganic layer may include at least one of the above-described materials, but the present disclosure is not limited thereto.

A gate GT1 of the transistor TFT is located on the first insulating layer 10. The gate GT1 may be a portion of a metal pattern. The gate GT1 overlaps the active area AC1. The gate GT1 may function as a mask in a process of doping the semiconductor pattern. The gate GT1 may include titanium (Ti), silver (Ag), an alloy containing silver (Ag), molybdenum (Mo), an alloy containing molybdenum (Mo), aluminum (Al), an alloy containing aluminum (Al), an aluminum nitride (AIN), tungsten (W), a tungsten nitride (WN), copper (Cu), an indium tin oxide (ITO), an indium zinc oxide (IZO), or the like, but the present disclosure is not particularly limited thereto.

A second insulating layer 20 may be located on the first insulating layer 10 to cover the gate GT1. A third insulating layer 30 may be located on the second insulating layer 20. A storage electrode CT may be located between the second insulating layer 20 and the third insulating layer 30. The storage electrode CT may overlap the gate GT1. The gate GT1 and the storage electrode CT may form a capacitor included in a driving circuit of the pixel PX (see FIG. 4).

A first connection electrode CNE1 may be located on the third insulating layer 30. The first connection electrode CNE1 may be connected to the drain area DE1 of the transistor TFT through a contact hole passing through the first insulating layer 10, the second insulating layer 20, and the third insulating layer 30.

A fourth insulating layer 40 may be located on the third insulating layer 30. A second connection electrode CNE2 may be located on the fourth insulating layer 40. The second connection electrode CNE2 may be connected to the first connection electrode CNE1 through a contact hole passing through the fourth insulating layer 40. A fifth insulating layer 50 may be located on the fourth insulating layer 40, and may cover the second connection electrode CNE2. A laminated structure of the first insulating layer 10 to the fifth insulating layer 50 is only by way of example, and an additional conductive layer and an additional insulating layer may be further arranged in addition to the first insulating layer 10 to the fifth insulating layer 50.

Each of the fourth insulating layer 40 and the fifth insulating layer 50 may be an organic layer. For example, the organic layer may include a general-purpose polymer, such as benzocyclobutene (BCB), polyimide, hexamethyldisiloxane (HMDSO), polymethylmethacrylate (PMMA), and polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A first light-emitting element LD-R may include a first electrode AE (or a pixel electrode), a light-emitting layer EL, and a second electrode CE (or a common electrode). The first electrode AE may be located on the fifth insulating layer 50. The first electrode AE may be a (semi)transmissive electrode or a reflective electrode. The first electrode AE may include a reflective layer formed of Ag, Mg, Al, Pt, Pd, Au, Ni, Nd, Ir, Cr, or a compound thereof, and a transparent or semitransparent electrode layer formed on the reflective layer. The transparent or semitransparent electrode layer may include at least one selected from the group including an indium tin oxide (ITO), an indium zinc oxide (IZO), an indium gallium zinc oxide (IGZO), a zinc oxide (ZnO) or an indium oxide (In2O3), or an aluminum-doped zinc oxide (AZO). For example, the first electrode AE may include a laminated structure of ITO/Ag/ITO.

A pixel-defining film PDL may be located on the fifth insulating layer 50. A light-emitting opening P-OP, through which at least a portion of the first electrode AE of the first light-emitting element LD-R is exposed, may be defined in the pixel-defining film PDL. The pixel-defining film PDL in a first area A1 may cover a portion of the first electrode AE.

A light-emitting area in which light generated by the first light-emitting element LD-R is substantially provided may be determined by an area of the light- emitting opening P-OP defined in the pixel-defining film PDL. The peripheral area NPXA adjacent to the first light-emitting area PXA-R may be defined as an area overlapping the pixel-defining film PDL.

In one or more embodiments, a hole control layer may be located between the first electrode AE and the light-emitting layer EL. The hole control layer may include a hole transport layer, and may further include a hole injection layer. An electron control layer may be located between the light-emitting layer EL and the second electrode CE. The electron control layer may include an electron transport layer and may further include an electron injection layer.

An encapsulation layer 140 may be located on the first light-emitting element LD-R. The encapsulation layer 140 may include a first inorganic encapsulation layer 141, an organic encapsulation layer 142, and a second inorganic encapsulation layer 143 that are sequentially laminated, but layers constituting the encapsulation layer 140 are not limited thereto.

The first inorganic encapsulation layer 141 and the second inorganic encapsulation layer 143 may protect a light-emitting element layer 130 from moisture and oxygen, and the organic encapsulation layer 142 may protect the light-emitting element layer 130 from foreign substances, such as dust particles. The first inorganic encapsulation layer 141 and the second inorganic encapsulation layer 143 may include inorganic materials. The first inorganic encapsulation layer 141 and the second inorganic encapsulation layer 143 may include a silicon nitride layer, a silicon oxy nitride layer, a silicon oxide layer, a titanium oxide layer, or an aluminum oxide layer. The organic encapsulation layer 142 may include an organic material. The organic encapsulation layer 142 may include at least one of an acryl-based resin, a methacryl-based resin, a polyisoprene, a vinyl-based resin, an epoxy-based resin, a urethane-based resin, a cellulose-based resin, a siloxane-based resin, a polyimide-based resin, a polyamide-based resin, or a phenylene-based resin.

A light control layer 200 may be located on a display panel 100. The light control layer 200 may adjust an emission rate of light provided from the light-emitting element layer 130 according to an area of the display panel 100.

The light control layer 200 may include a multi-layered structure. The light control layer 200 may include a light-shielding pattern BM, a first cover layer OC1 covering the light-shielding pattern BM, a bank BK located on the first cover layer OC1, lenses LS1 and LS2, and a second cover layer OC2 covering the bank BK and the lenses LS1 and LS2, although the present disclosure is not particularly limited thereto.

The light-shielding pattern BM may be located on the display panel 100 and overlap the pixel-defining film PDL. The light-shielding pattern BM shields light emitted from the first light-emitting element LD-R at an angle (e.g., a predetermined angle). That is, a viewing angle may be controlled by reducing light extraction in a light viewing angle direction.

FIG. 6A representatively illustrates a case in which the light-shielding pattern BM is located as one layer, but the light-shielding pattern BM may have a multi-layered structure to adjust the viewing angle. Because a lens structure of the present disclosure may be applied to various light-shielding pattern structures, the following description will be made using a case in which the light-shielding pattern BM is included as one layer, but the present disclosure is not limited thereto.

The first cover layer OC1 may be located on the light-shielding pattern BM. The first cover layer OC1 may cover the light-shielding pattern BM, and may flatten an upper portion thereof. The first cover layer OC1 may include an organic material. For example, the first cover layer OC1 may include at least one of an acryl-based resin, a methacryl-based resin, a polyisoprene, a vinyl-based resin, an epoxy-based resin, a urethane-based resin, a cellulose-based resin, a siloxane-based resin, a polyimide-based resin, a polyamide-based resin, or a phenylene-based resin.

When a multi-layer structure is applied to the light-shielding pattern BM, the viewing angle may be variously adjusted. However, as the light-shielding pattern BM increases, the amount of light absorbed by the light-shielding pattern BM among the light emitted from the first light-emitting element LD-R may be increased. Thus, the amount of light passing through the window WM (see FIG. 3) in the display device DD (see FIG. 3) may be decreased. To reduce or prevent a decrease in the amount of light, a structure for increasing the amount of light may be added onto the light-shielding pattern BM and the first cover layer OC1.

The bank BK may be located on the first cover layer OC1. The bank BK may be located on the light-shielding pattern BM. An opening OP corresponding to a side surface of the bank BK overlapping the first light-emitting element LD-R may be defined in the bank BK. A width of the bank BK may be varied in a direction in which light provided from the first light-emitting area PXA-R is emitted (e.g., in the third direction DR3). In one or more embodiments, the width of the bank BK may increase along a direction in which light is emitted.

The bank BK may include a polyimide-based resin. However, the present disclosure is not limited thereto, and the bank BK may include a light-absorbing material. The light-absorbing material may include a black pigment or a black dye. Carbon black may be used as the black pigment or the black dye, but one or more embodiments is not limited thereto.

The first lens LS1 may be located inside the opening OP of the bank BK and may overlap the first light-emitting element LD-R. The first lens LS1 may be a resin pattern in which optical particles are mixed with a base resin.

The first lens LS1 may fill the opening OP of the bank BK, and may protrude from an upper end of the bank BK in the third direction DR3. The first lens LS1 may cover the opening OP of the bank BK, but may not cover an upper surface of the bank BK (e.g., may not overlap the upper surface of the bank BK in plan view). The first lens LS1 may have a shape protruding from the bank BK such that a thickness of the first lens LS1 increases from a point at which the first lens LS1 meets an upper end of the opening OP to a center of the first lens LS1 (e.g., on a plane). An upper surface of the first lens LS1 is defined as a lens surface LSS. The upper surface of the first lens LS1 may be a curved surface. A protruding shape of the first lens LS1 is caused by surface energy of the bank BK, surface tension of the first lens LS1, and a material characteristic thereof. This will be described below with respect to a manufacturing method.

A width of the first lens LS1 on a plane may correspond to the first light-emitting area PXA-R. In this case, a thickness of the first lens LS1 in the third direction DR3 may have a value of about 0.25 times to about 0.3 times the width of the first lens LS1 on a plane. This may be applied when the first lens LS1 is located in the one light-emitting area described with respect to FIG. 6A.

The plurality of second lenses LS2 may be arranged on (e.g., above) the first lens LS1. The second lens LS2 may be a resin pattern in which optical particles are mixed with the base resin, and a type or ratio of the optical particles may be different from that of the first lens LS1. A refractive index of the second lens LS2 may be different from a refractive index of the first lens LS1.

One surface of each of the plurality of second lenses LS2 may contact the lens surface LSS. Among surfaces of the plurality of second lenses LS2, an upper surface that is not contacting the lens surface LSS and defined in a direction opposite to the lens surface LSS may be a curved surface. A curvature of the curved surface of the upper surfaces of the second lenses LS2 may be different from a curvature of the lens surface LSS.

The plurality of second lenses LS2 may include a second-first lens LS2-1 having a first refractive index and a second-second lens LS2-2 having a second refractive index. FIG. 6A illustrates a total of four lenses such that there are two second-first lenses LS2-1 and two second-second lenses LS2-2 on a cross section.

The second-first lenses LS2-1 may be adjacent to a center CP of the first lens LS1, and the second-second lenses LS2-2 may be farther from the center CP of the first lens LS1 than the second-first lenses LS2-1. The second-first lenses LS2-1 and the second-second lenses LS2-2 may be symmetrical to each other in a left-right direction on a cross section.

In the present disclosure, a color is displayed to distinguish the second-first lenses LS2-1 and the second-second lenses LS2-2 from each other, but the second-first lenses LS2-1 and the second-second lenses LS2-2 may be transparent. Hereinafter, the views illustrating the second-first lenses LS2-1 and the second-second lenses LS2-2 are equally applied. Detailed descriptions of the second-first lenses LS2-1 and the second-second lenses LS2-2 will be provided below in FIGS. 6B and 6C.

The second cover layer OC2 may be located on the first lens LS1 and the second lens LS2 to cover the first lens LS1 and the second lens LS2. The second cover layer OC2 may flatten upper portions of the first lens LS1 and the second lens LS2. The second cover layer OC2 may be formed of the same material as the first cover layer OC1.

A reflection reduction layer (e.g., reflection-preventing layer) 300 may be located on the light control layer 200. The reflection reduction layer 300 may be coupled to the light control layer 200 by an adhesive layer. The adhesive layer may be a pressure sensitive adhesive (PSA) film or an optically clear adhesive (OCA) member.

The reflection reduction layer 300 may reduce reflectance of external light. The reflection reduction layer 300 may include an optical film. The optical film may include a polarizing film. The optical film may further include a retarder film. The retarder film may include at least one of a λ/2 retarder film or a λ/4 retarder film.

In one or more embodiments, an input sensor may be additionally included. The input sensor may sense an external input applied from the outside. The external input may include various types of inputs, such as a portion of a body of the user, light, heat, a pen, and/or pressure. The input sensor may be formed on a display panel through a continuous process.

As an example, the input sensor may be located on the display panel 100. The input sensor may be directly located on the display panel 100. In the specification, the wording “a component B is directly located on a component A” may mean that no third component is located between the component A and the component B. For example, an adhesive layer may not be located between, or may be omitted from between, the input sensor and the display panel 100.

As an example, the input sensor may overlap or may be engaged with the light control layer 200. For example, when the light-shielding pattern BM is formed in multiple layers in the light control layer 200, the input sensor may be located between the layers of the light-shielding pattern BM, or the light-shielding pattern BM may cover an input signal line.

FIG. 6A illustrates that the bank BK and the first lens LS1 are arranged on the first cover layer OC1, but the bank BK and the first lens LS1 may be arranged on the encapsulation layer 140, arranged on a color filter, or arranged on a color conversion function layer, in one or more embodiments.

FIG. 6B is an enlarged plan view of a portion of a light control layer according to one or more embodiments.

FIG. 6B illustrates the bank BK, the first lens LS1, the second-first lenses LS2-1, and the second-second lenses LS2-2 of FIG. 6A.

The bank BK may surround an area corresponding to the light-emitting element LD-R (see FIG. 6A) on a plane. The first lens LS1 may fill an inner area of the bank BK. The plurality of second lenses LS2 are arranged on the first lens LS1. A partial area of a lens surface of the first lens LS1 may be exposed from the second lenses LS2.

The second lenses LS2 may be aligned to have a matrix arrangement on a plane. The second-first lenses LS2-1 may be arranged adjacent to the center CP of the first lens LS1. The second-second lenses LS2-2 may be arranged to be further outward than the second-first lenses LS2-1 from the center CP of the first lens LS1.

The second-first lenses LS2-1 and the second-second lenses LS2-2 may include materials having different respective refractive indices. A function of a lens according to the refractive indices of the second-first lenses LS2-1 and the second-second lenses LS2-2 will be described in FIG. 6C.

FIG. 6C is an enlarged cross-sectional view of the portion of the display module according to one or more embodiments.

FIG. 6C is an enlarged view illustrating only the bank BK, the first lens LS1, the second-first lenses LS2-1, and the second-second lenses LS2-2 of the light control layer 200 (see FIG. 6A). A dotted line refers to a movement path of light generated by the light-emitting element LD-R (see FIG. 6A) located under the first lens LS1.

Referring to part (a) of FIG. 6C, the first lens LS1 may have a refractive index that is higher than that of the second-second lens LS2-2, and the second-second lens LS2-2 may have a refractive index higher than that of the second-first lens LS2-1. As an example, the refractive index of the first lens LS1 may be about 1.70, the refractive index of the second-second lens LS2-2 may be about 1.65, and the refractive index of the second-first lens LS2-1 may be about 1.60.

In part (a) of FIG. 6C, light generated by the light-emitting element LD-R (see FIG. 6A) may be condensed in a central portion while passing through the first lens LS1 and the second lens LS2. Brightness of the display device DD (see FIG. 3) may be improved through the refractive indices of the lenses as illustrated in FIG. 6(a).

Referring to part (b) of FIG. 6C, the first lens LS1 may have a refractive index that is less than that of the second-second lens LS2-2, and the second-second lens LS2-2 may have a refractive index that is less than that of the second-first lens LS2-1. As an example, the refractive index of the first lens LS1 may be about 1.60, the refractive index of the second-second lens LS2-2 may be about 1.65, and the refractive index of the second-first lens LS2-1 may be about 1.70.

In part (b) of FIG. 6C, light generated by the light-emitting element LD-R (see FIG. 6A) may be emitted while passing through the first lens LS1 and the second lens LS2. A viewing angle of the display device DD (see FIG. 3) may be improved through the refractive indices of the lenses as illustrated in FIG. 6(b).

The light control layer 200 may function differently according to a refractive index arrangement of a lens structure devised in the present disclosure.

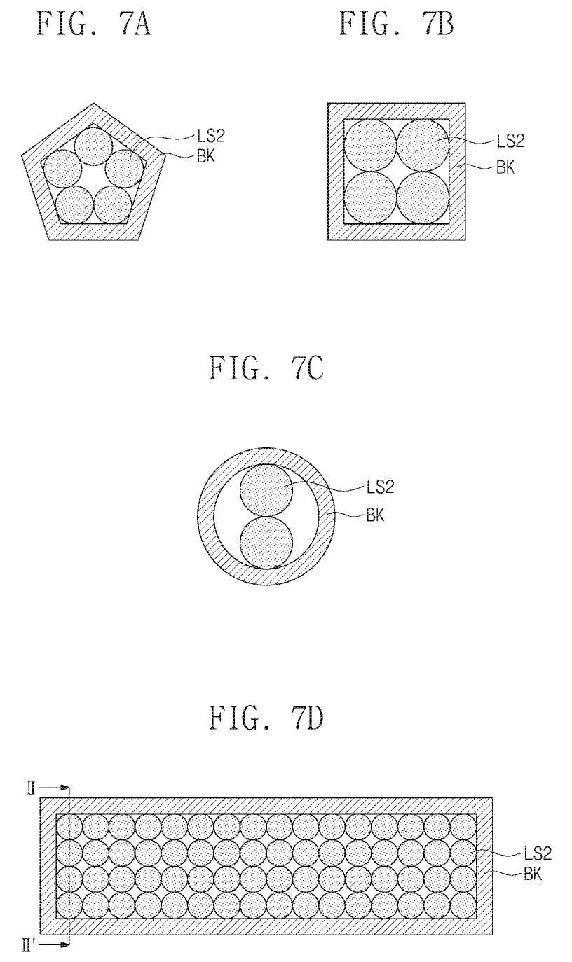

FIGS. 7A-7D are plan views of a light controlling layer according to one or more embodiments.

FIGS. 6A-6C illustrate a structure in which one first lens is located on one light-emitting area, but the lens structure of the present disclosure may have various shapes.

Because the bank BK has a shape to surround the light-emitting area, a shape of the bank BK may be determined according to a shape of the pixel. By way of example, referring to FIG. 7A, the bank BK may have a pentagonal shape. Referring to FIG. 7B, the bank BK may have a square (e.g., generally square) shape. Referring to FIG. 7C, the bank BK may have a circular shape. A shape of the first lens LS1 is determined by the bank BK. The second lens LS2 may be variously located according to the shape and a size of the bank BK, but the present disclosure is not particularly limited to the illustration.

The light-emitting areas in the one display module DM (see FIG. 4) may have different respective sizes according to a corresponding color of emitted light and a pixel structure. In this case, the size of the bank BK may be changed according to the size of the corresponding light-emitting area in the same display module.

The opening OP of the bank BK may overlap a plurality of light-emitting elements. FIG. 7D illustrates that the bank BK surrounds the plurality of light-emitting elements. The first lens LS1 may overlap the plurality of light-emitting elements. In this structure, process operations may be reduced, suitable manufacturing precision is lowered, and thus probability of defects may be reduced.

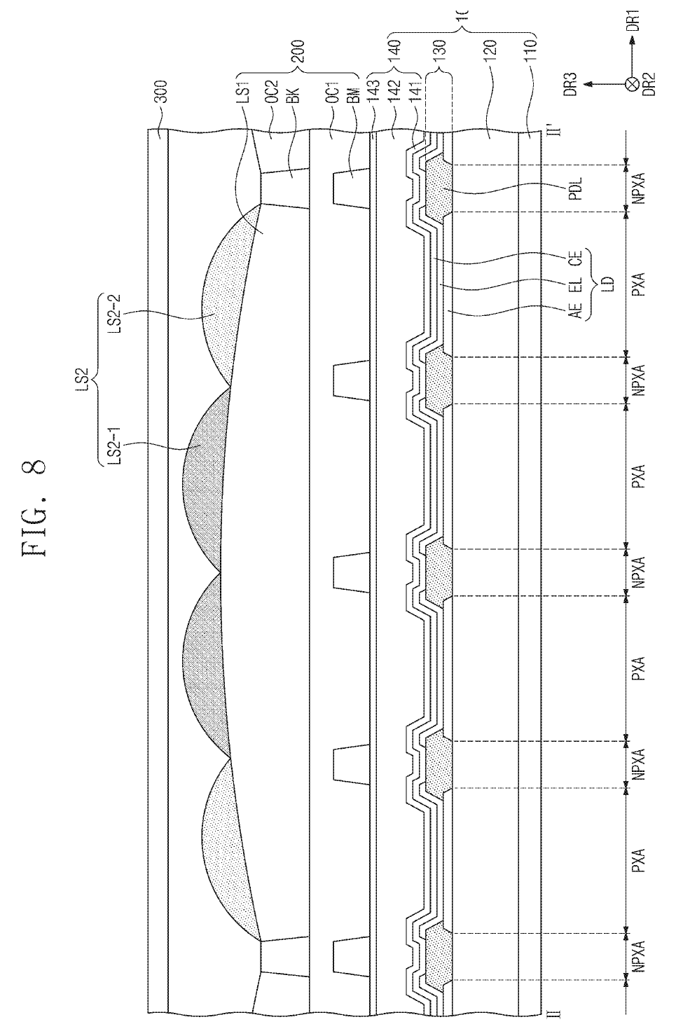

FIG. 8 is a cross-sectional view taken along the line II-II′ of FIG. 7D according to one or more embodiments.

The components identical/similar to those described with reference to FIG. 6A are designated by the identical/similar reference numerals, a duplicated description thereof will be omitted, and differences therebetween will be mainly described.

FIG. 8 illustrates an arrangement relationship between the lens structure and the plurality of light-emitting elements.

In the specification, the bank BK may overlap a portion of the pixel-defining film PDL. The opening OP of the bank BK overlaps a plurality of pixel areas PXA. The first lens LS1 overlaps the plurality of pixel areas PXA.

Each of the plurality of second lenses LS2 may correspond to a corresponding light-emitting element LD among the plurality of light-emitting elements. It is illustrated that the second lenses LS2 respectively correspond to the plurality of pixel areas PXA, but present disclosure is not particularly limited thereto, and the plurality of second lenses LS2 may be located in the one light-emitting area.

The contents described in FIG. 6C may be similarly applied to the refractive indices of the first lens LS1 and the second lenses LS2. That is, the second-first lenses LS2-1 and the second-second lenses LS2-2 may have the refractive indices that are different from the refractive index of the first lens LS1, and thus light may be emitted or condensed.

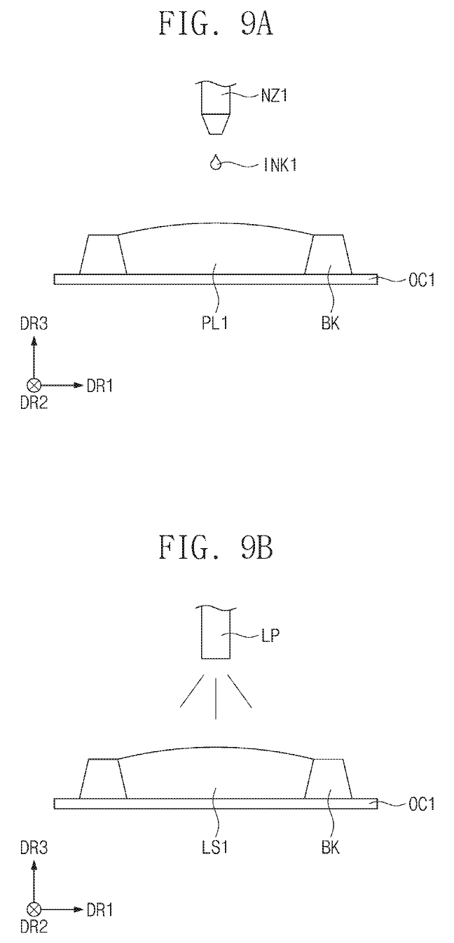

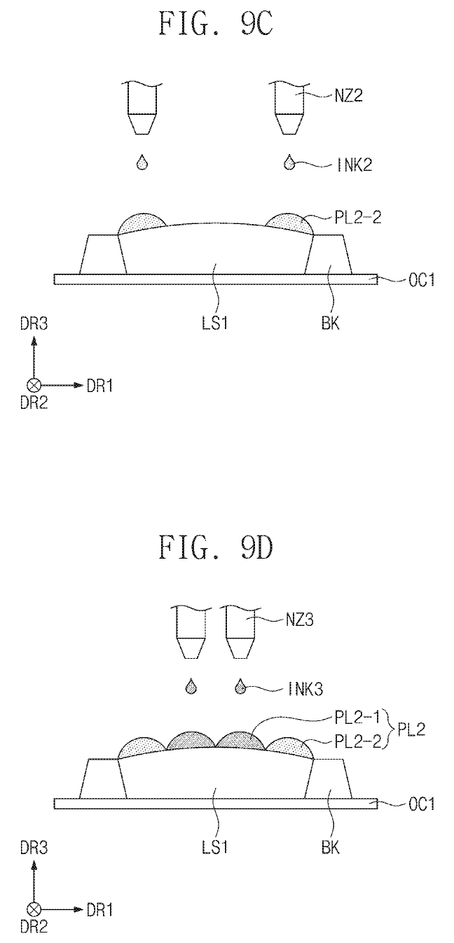

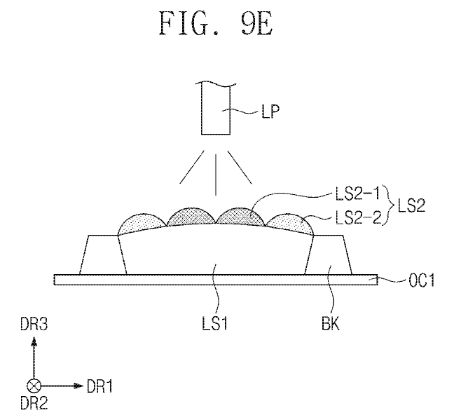

FIGS. 9A-9E are views for describing a method of manufacturing a display device according to one or more embodiments.

The components identical/similar to those described with reference to FIGS. 1-8 are designated by the identical/similar reference numerals, a duplicated description thereof will be omitted, and differences therebetween will be mainly described.

Referring to FIG. 9A, the bank BK in which an opening overlapping the light-emitting element is defined may be formed on the display panel. The bank BK may be directly located on the first cover layer OC1. The bank BK may include a polyimide- based resin. The bank BK may have a shape formed by depositing a polyimide-based resin material, applying a photoresist material, and exposing and patterning the same.

A nozzle NZ1 may discharge a first resin material (e.g., a liquid first resin material) INK1 into the opening OP, and thus a first preliminary lens PL1 is formed. The first resin material INK1 may fill an inside of the opening OP of the bank BK. The first resin material INK1 may cover the entire opening OP of the bank BK. A central portion thereof is convex by surface tension due to the amount of first resin material INK1 that is further discharged after the first resin material INK1 fills the opening OP of the bank BK. The first preliminary lens PL1 has a shape protruding from the bank BK in the third direction DR3.

The surface energy of the bank BK may have a value of about 20 mJ/m² to about 30 mJ/m². For example, the surface energy of the bank BK may be in a range of about 21 mJ/m² to about 24 mJ/m². When the surface energy of the bank BK is about 20 mJ/m² or less, the first resin material INK1 may not be adsorbed to the bank BK, and when the surface energy is about 30 mJ/m² or more, coupling properties with the first resin material INK1 may be high, and thus a curved surface of the first resin material INK1 may be unevenly formed.

The first resin material INK1 may be formed by mixing/blending optical particles for increasing the refractive indices with an ultraviolet (UV)/thermosetting base resin. The base resin may include an acrylic resin, a polyurethane resin, an epoxy resin, a silicone resin, or a polyester resin before curing. The optical particles mixed/blended with the base resin to increase the refractive indices may include silica (SiO₂), a titanium dioxide (TiO₂), a boron oxide (B₂O₃), or the like.

When surface tension of the first resin material INK1 has a value of about 26 dyne/cm to about 38 dyne/cm, the first resin material INK1 is formed in a convex shape in which an upper portion thereof has a curved surface.

The surface energy of the bank BK and the surface tension of the first resin material INK1 may suitably have not only respective numerical values, but also may have numerical relationships therebetween. When the surface tension of the first resin material INK1 is not greater than or equal to the surface energy of the bank BK by a value (e.g., a predetermined value) or more, the curved surface might not be formed. For example, when the surface energy of the bank BK is about 20 J/m², the first resin material INK1 may not form a curved surface when the surface tension of the first resin material INK1 is about 22 dyne/cm or less. For example, when the surface energy of the bank BK is about 38 J/m², the first resin material INK1 may not form a curved surface when the surface tension of the first resin material INK1 is about 40 dyne/cm or less. When the curved surface of the lens is not formed, an interface of the lens may not be sufficiently formed, and thus light might not be properly refracted.

When a material having a surface tension of about 38 dyne/cm or more is used, the curved surface of the lens may have an excessive convex shape. When the curved surface of the lens is excessively convex, a focal length of the lens may be shortened, and thus the lens may not fully perform a function thereof. Further, when the curved surface of the lens is excessively convex, the probability of defects in which ink is unevenly applied or the ink flows down when other resin materials are laminated thereon may increase.

Referring to FIG. 9B, a light source LP may cure the first preliminary lens PL1 (see FIG. 9A) so that the first lens LS1 is formed. A thermal-curing method, in addition to UV-curing using a UV lamp, may be used as the light source LP.

Referring to FIG. 9C, a second resin material (e.g., a liquid second resin material) INK2 may be provided such that a plurality of second-second preliminary lenses PL2-2 are formed on the upper surface of the first lens LS1.

Referring to FIG. 9D, after the second resin material INK2 is discharged in an inkjet method to form the second-second preliminary lens PL2-2, a third resin material (e.g., a liquid third resin material) INK3 may be provided so that a plurality of second-first preliminary lenses PL2-1 are formed.

Unlike the first resin material INK1, the second resin material INK2 and the third resin material INK3 are directly applied to the upper surface of the first lens LS1. Thus, the second resin material INK2 and the third resin material INK3 may have values of surface tension that are different from that of the first resin material INK1. A difference between surface tensions of the second resin material INK2 and the first resin material INK1 may have a value of about -2 dyne/cm to about +2 dyne/cm. A difference between surface tensions of the third resin material INK3 and the first resin material INK1 may have a value of about -2 dyne/cm to about +2 dyne/cm. The surface tensions of the second resin material INK2 and the third resin material INK3 may be in a range of about 24 dyne/cm to about 40 dyne/cm.

The second resin material INK2 and the third resin material INK3 may be directly laminated on the upper surface of the first lens LS1 without a separate bank structure.

Because the second resin material INK2 and the third resin material INK3 have different surface tensions from that of the first resin material INK1, a curved surface of the second-second preliminary lens PL2-2 formed of the second resin material INK2, and a curved surface of the second-first preliminary lens PL2-1 formed of the third resin material INK3, may have different curvatures from that of the first lens LS1.

Like the first resin material INK1, the second resin material INK2 and the third resin material INK3 may be obtained by adding optical particles for increasing the refractive indices to the UV/thermosetting base resin. In the first resin material INK1, the second resin material INK2, and the third resin material INK3, optical particles may be added to different base resins. The first resin material INK1, the second resin material INK2, and the third resin material INK3 may have different refractive indices. For example, the first resin material INK1, the second resin material INK2, and the third resin material INK3 may be materials having different types and ratios of optical particles.

Referring to FIG. 9E, the second-first preliminary lens PL2-1 and the second-second preliminary lens PL2-2 are cured to form the second lens LS2.

A manufacturing method of forming a two-layer lens according to an inkjet method has been described above.

When a lens is manufactured according to a photolithography method, it is difficult to bring an upper lens surface into direct contact with a lower lens surface, a problem of a thickness according to a focal length of an upper lens may occur as a lower lens and the upper lens are spaced apart from each other, and a shape and material of the lens is limited according to limitations of the photolithography method.

As the lens is formed by an inkjet method, the upper lens may be directly laminated on the lower lens, and thus problems during the lamination of the lens occurring in the photolithography method may be resolved.

According to the present disclosure, a lens structure is formed using an inkjet method, and thus, a material is less limited, and a lens surface is suitably formed compared to a photo process.

Using an inkjet method, a structure in which a lens is directly located may be formed on the lens, a thickness of the entire panel may be reduced, and a focal length of the lens may be suitably adjusted.

As refractive indices of a lens located on an upper side and a lens located on a lower side are different from each other, a condensing effect of light generated by a light-emitting element may be increased, and in contrast, a diffusion effect of the light may be increased.

Although the description has been made above with reference to one or more embodiments of the present disclosure, those skilled in the art may understand that the present disclosure may be variously modified and changed without departing from the spirit and the technical scope of the present disclosure described in the appended claims. Accordingly, the technical scope of the present disclosure is not limited to the detailed description of the specification, but should be defined by the appended claims, with functional equivalents thereof to be included therein.

What is claimed is:

1. A display device comprising:
a light-emitting element;
a bank above the light-emitting element and defining an opening overlapping the light-emitting element;
a first lens inside the opening; and
second lenses contacting a lens surface of the first lens.

2. The display device of claim 1, wherein the lens surface of the first lens protrudes upwardly from an upper end of the bank.

3. The display device of claim 1, wherein the second lenses and the first lens comprise materials having different respective refractive indices.

4. The display device of claim 1, wherein upper surfaces of the first lens and the second lenses are curved and have different respective curvatures.

5. The display device of claim 1, wherein a partial area of the lens surface of the first lens is exposed between the second lenses in plan view.

6. The display device of claim 1, wherein the bank comprises an upper surface extending from the opening in a direction away from the light-emitting element.

7. The display device of claim 1, wherein the second lenses comprise a second-first lens having a first refractive index and a second-second lens having a second refractive index, and
wherein the second-second lens is further from a center of the first lens than the second-first lens is from the center of the first lens.

8. The display device of claim 7, wherein the first lens has a refractive index higher than a refractive index of the second-second lens, which is higher than a refractive index of the second-first lens.

9. The display device of claim 7, wherein the first lens has a refractive index that is less than a refractive index of the second-second lens, which is less than a refractive index of the second-first lens.

10. The display device of claim 7, wherein the second-first lens is provided in plural, and
wherein the second-second lens is provided in plural.

11. The display device of claim 1, wherein the light-emitting element is provided in plural,
wherein the opening is provided in plural, and
wherein the light-emitting elements respectively overlap the openings.

12. The display device of claim 11, wherein the second lenses overlap a corresponding one of the light-emitting elements.

13. The display device of claim 1, further comprising a pixel-defining film below the bank, and defining a light-emitting opening exposing a first electrode,
wherein the light-emitting element comprises the first electrode, a light-emitting layer, and a second electrode above the light-emitting layer.

14. The display device of claim 13, further comprising a light-shielding pattern above the pixel-defining film and below the bank.

15. An electronic device comprising:
a display device; and
a processor configured to control the display device,
wherein the display device comprises:
a light-emitting element;
a bank above the light-emitting element and defining an opening overlapping the light-emitting element;
a first resin pattern inside the opening and comprising a curved first surface protruding from the opening; and
second resin patterns on the first surface of the first resin pattern and comprising a curved second surface in a direction opposite to the light-emitting element.

16. The electronic device of claim 15, wherein the first surface and the second surface have different respective curvatures.

17. The electronic device of claim 15, wherein the first resin pattern and the second resin patterns comprise a base resin and optical particles and have different respective types or ratios of the optical particles.

18. The electronic device of claim 16, wherein the second resin patterns comprise a second-first resin pattern having a first refractive index and a second-second resin pattern having a second refractive index, and
wherein the second-second resin pattern is located further outwardly from a center of the first resin pattern than the second-first resin pattern from the center of the first resin pattern.

19. The electronic device of claim 18, wherein the first resin pattern, the second-first resin pattern, and the second-second resin pattern have different respective curvatures.

20. A method of manufacturing a display device, the method comprising:
forming a bank above a display panel, defining an opening overlapping a light-emitting element, and having surface energy in a range of about 20 mJ/m² to about 30 mJ/m²;
providing a liquid first resin material to the opening to form a first preliminary lens comprising a lens surface having surface tension in a range of about 26 dyne/cm to about 38 dyne/cm;
curing the first preliminary lens to form a first lens;
providing a liquid second resin material to form second preliminary lenses on the first lens; and
curing the second preliminary lenses to form second lenses.
